(19) United States
(12) Patent Application Publication
(10) Pub. No.: US 2026/0099439 A1
(43) Pub. Date: Apr. 9, 2026

(54) Clock phase control circuits and electronic device

(71) Applicant: Silicon Motion, Inc., Hsinchu County (TW)

(72) Inventor: Han-Cheng Huang, Taipei City (TW)

(73) Assignee: Silicon Motion, Inc., Hsinchu County (TW)

(21) Appl. No.: 19/055,503

(22) Filed: Feb. 18, 2025

Related U.S. Application Data
(60) Provisional application No. 63/705,023, filed on Oct. 8, 2024.

(30) Foreign Application Priority Data
Jan. 14, 2025 (TW) 114101490

(51) Int. Cl. G06F 12/02; G06F 1/04; G11C 16/32; H03K 19/21; H03L 7/081

(52) U.S. Cl. CPC G06F 12/0246; G06F 1/04; G11C 16/32; H03K 19/21; H03L 7/0812

(57) ABSTRACT

A clock phase control circuit includes a sampling circuit and a phase monitoring circuit. The sampling circuit receives a plurality of reference clock signals and, in response to a read command, samples data read from a memory device according to the reference clock signals to obtain a plurality of sampling results. The reference clock signals are generated based on a fundamental clock signal with different candidate phases. The phase monitoring circuit receives the sampling results and determines an optimal phase according to the sampling results. The data read from the memory device comprises data in one or more data blocks which are sequentially received in response to the read command. In response to an end of each data block, a sampling phase of the fundamental clock signal to sample the data read from the memory device is adjusted according to the optimal phase.

### CROSS REFERENCE TO RELATED APPLICATIONS

This application claims the benefit of U.S. Provisional Application No. 63/705,023, filed on Oct. 8, 2024. The content of the application is incorporated herein by reference.

### BACKGROUND OF THE INVENTION

### 1. Field of the Invention

The present invention is related to a clock phase control circuit to effective control the clock phase utilized for sampling data read from a memory device.

### 2. Description of the Prior Art

With the rapid growth of data storage technology in recent years, many data storage devices-such as memory cards manufactured in compliance with the Secure Digital (SD)/Multi Media Card (MMC) standards, Compact Flash (CF) standards, Memory Stick (MS) standards or Extreme Digital (XD) standards, as well as Solid State Disk (SSD) drives, Embedded Multi Media Cards (eMMC) and Universal Flash Storage (UFS)—have been used widely for a variety of purposes. In addition, the data rate of the data storage devices keeps increasing with the advance of data storage technology as well.

However, as the data rate increases, the margin to correctly latch or sample data decreases, causing the error rate of latching or sampling data to possibly increase in certain conditions. Therefore, improving performance of the data storage devices is an important issue in the field of data storage.

### SUMMARY OF THE INVENTION

According to an embodiment of the invention, a clock phase control circuit comprises a sampling circuit and a phase monitoring circuit. The sampling circuit receives a plurality of reference clock signals and, in response to a read command, samples data read from a memory device according to the reference clock signals to obtain a plurality of sampling results. The reference clock signals are generated based on a fundamental clock signal with different candidate phases. The phase monitoring circuit receives the sampling results and determines an optimal phase according to the sampling results. The data read from the memory device comprises data in one or more data blocks which are sequentially received in response to the read command, and after an end of each data block, a sampling phase of the fundamental clock signal to sample the data read from the memory device is adjusted according to the optimal phase.

According to an embodiment of the invention, an electronic device coupled to a data storage device comprises a receiving circuit receiving data read from a memory device of the data storage device and a signal processing circuit processing the date. The data read from the memory device comprises data in one or more data blocks which are sequentially received in response to a read command. The signal processing circuit comprises a clock signal generating circuit and a clock phase control circuit. The clock signal generating circuit generates a plurality of reference clock signals based on a fundamental clock signal with different candidate phases. The candidate phases comprise a sampling phase of the fundamental clock signal currently set to sample the data. The clock phase control circuit consecutively determines an optimal phase according to a plurality of sampling results obtained according to the reference clock signals and provides information regarding the optimal phase to the clock signal generating circuit to adjust the sampling phase of the fundamental clock signal after an end of each data block.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows an exemplary block diagram of a data storage device according to an embodiment of the invention.

FIG. 2 shows an exemplary circuit diagram of a portion of circuits in the host interface and a portion of circuits in the device interface according to an embodiment of the invention.

FIG. 3 shows an exemplary timing diagram of data transmission in response to a read command issued by the host device according to an embodiment of the invention.

FIG. 4 is a schematic diagram of the proposed clock phase control implemented by the clock signal generating circuit and the clock phase control circuit according to an embodiment of the invention.

FIG. 5 shows an exemplary circuit diagram of the phase control circuit according to an embodiment of the invention.

FIG. 6 shows an exemplary state machine to perform clock phase control according to an embodiment of the invention.

### DETAILED DESCRIPTION

In the following, numerous specific details are described to provide a thorough understanding of embodiments of the invention. However, one of skilled in the art will understand how to implement the invention in the absence of one or more specific details, or relying on other methods, elements or materials. In other instances, well-known structures, materials or operations are not shown or described in detail in order to avoid obscuring the main concepts of the invention.

Reference throughout this specification to “one embodiment”, “an embodiment”, “one example” or “an example” means that a particular feature, structure or characteristic described in connection with the embodiment or example is included in at least one embodiment of a plurality of embodiments. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or sub-combinations in one or more embodiments or examples.

In addition, in order to make the objects, features and advantages of the invention more comprehensible, specific embodiments of the invention are set forth in the accompanying drawings. This description is made for the purpose of illustrating the general principles of the invention and should not be taken in a limiting sense. It should be understood that the following embodiments can be implemented by software, hardware, firmware, or any combination thereof.

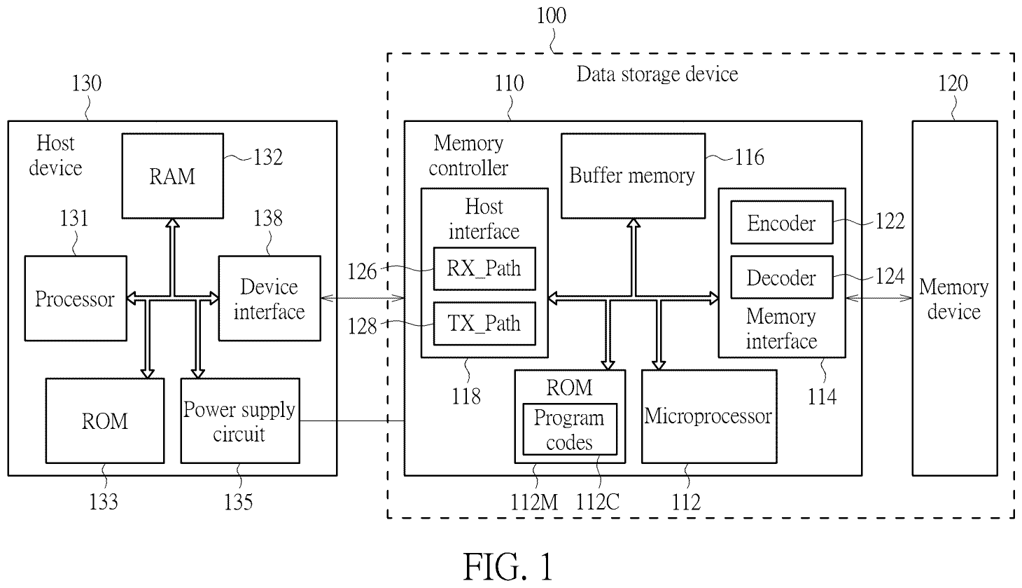

FIG. 1 shows an exemplary block diagram of a data storage device according to an embodiment of the invention. The data storage device 100 may comprise a memory device 120 and a memory controller 110. The memory controller 110 is configured to access the memory device 120 and control operations of the memory device 120. The memory device 120 may be a non-volatile (NV) memory (e.g., a Flash memory) device and may comprise one or more memory elements (e.g., one or more Flash memory dies, or one or more Flash memory chip, or the likes).

The data storage device 100 may be coupled to a host device 130. The host device 130 may comprise at least one processor 131, at least one random access memory (RAM) 132, such as at least one dynamic RAM (DRAM), at least one static RAM (SRAM), etc., at least one read only memory (ROM) 133, a power supply circuit 135 and a device interface 138.

The host device 130 may access the data storage device 100 through the device interface 138. The processor 131, the device interface 138, the RAM 132 and the ROM 133 may be coupled to each other through a bus, and may be coupled to the power supply circuit 135 to obtain power. The processor 131 may be arranged to control operations of the host device 130. The ROM 133 is configured to store program codes. The processor 131 may be configured to execute the program codes, thereby controlling operations of the host device 130.

The power supply circuit 135 may be arranged to provide the processor 131, the device interface 138, the RAM 132 and ROM 133 with power as well as provide the data storage device 100 with power through the bus or the power lines. For example, the power supply circuit 135 may output one or more driving voltages to the data storage device 100. The data storage device 100 may obtain the one or more driving voltages from the host device 130 as the power of the data storage device 100 and provide the host device 130 with storage space.

According to an embodiment of the invention, the memory controller 110 may comprise a microprocessor 112, a ROM 112M, a memory interface 114, a buffer memory 116 and a host interface 118. The ROM 112M is configured to store program codes 112C. The microprocessor 112 is configured to execute the program codes 112C, thereby controlling access to the memory device 120. The program codes 112C may comprise one or more program modules, such as the boot loader code. When the data storage device 100 obtains power from the host device 130, the microprocessor 112 may perform an initialization procedure of the data storage device 100 by executing the program codes 112C. In the initialization procedure, the microprocessor 112 may load a group of In-System Programming (ISP) codes (not shown in FIG. 1) from the memory device 120. The microprocessor 112 may execute the group of ISP codes, so that the data storage device 100 has various functions. According to an embodiment of the invention, the group of ISP codes may comprise, but are not limited to: one or more program modules related to memory access (e.g., read, write and erase), such as a read operation module, a table lookup module, a wear leveling module, a read refresh module, a read reclaim module, a garbage collection module, a sudden power off recovery (SPOR) module and an uncorrectable error correction code (UECC) module, respectively provided for performing the operations of read, table lookup, wear leveling, read refresh, read reclaim, garbage collection, SPOR and error handling for detected UECC error.

The memory interface 114 may comprise an encoder 122 and a decoder 124. The encoder 122 is configured to encode the data to be written into the memory device 120, such as performing ECC encoding. The decoder 124 is configured decode the data read out from the memory device 120.

Typically, the memory device 120 may comprise a plurality of memory elements, such as a plurality of Flash memory dies or Flash memory chips, and each memory element may comprise a plurality of memory blocks. The access unit of an erase operation performed by the memory controller 110 on the memory device 120 may be one memory block. In addition, a memory block may record (comprise) a predetermined number of pages, for example, the physical pages, and the access unit of a write operation or a read operation performed by the memory controller 110 on the memory device 120 may be one page.

In practice, the memory controller 110 may perform various control operations by using its own internal components. For example, the memory controller 110 may use the memory interface 114 to control the access operations (especially the access operation for at least a memory block or at least a page) of the memory device 120, use the buffer memory 116 to perform necessary data buffer operations, and use the host interface 118 to communicate with the host device 130. The host interface 118 may comprise at least a signal reception path RX_Path 126 and a signal transmission path TX_Path 128 for processing the data and signals received from and to be transmitted to the host device 130. The signal reception path RX_Path 126 and the signal transmission path TX_Path 128 may respectively comprise one or more signal processing circuits to perform necessary signal processing.

In an embodiment of the invention, the memory controller 110 may use the host interface 118 to communicate with the host device 130 in compliance with a standard communication protocol. For example, the standard communication protocol may comprise (but is not limited to) the Universal Serial Bus (USB) standard, the SD interface standard, the Ultra High Speed-I (UHS-I) interface standard, the Ultra High Speed-II (UHS-II) interface standard, the CF interface standard, the MMC interface standard, the eMMC interface standard, the UFS interface standard, the Advanced Technology Attachment (ATA) standard, the Serial ATA (SATA) standard, the Peripheral Component Interconnect Express (PCI-E) standard, the Parallel Advanced Technology Attachment (PATA) standard, etc.

In an embodiment, the buffer memory 116 may be implemented by a RAM. For example, the buffer memory 116 may be an SRAM, but the invention should not be limited thereto. In other embodiments, the buffer memory 116 may be a DRAM.

In an embodiment of the invention, the data storage device 100 may be a portable storage device (for example, the memory card in compliance with the SD/MMC, CF, MS and/or XD standard), and the host device 130 may be an electronic device, such as a mobile phone, a notebook computer, a desktop computer . . . etc., capable of connecting to the data storage device. In another embodiment of the invention, the data storage device 100 may be a solid state hard disk or an embedded storage device in compliance with the UFS or the eMMC standards, and may be equipped in an electronic device such as a mobile phone, a notebook computer, or a desktop computer. In such an embodiment, the host device 130 may be a processor of the electronic device.

The host device 130 may issue commands, such as the read command or the write command, to the data storage device 100, so as to access the data stored in the memory device 120, or the host device 130 may issue commands to further control or manage the data storage device 100.

The data storage device 100 may operate based on a clock signal CLK. In some embodiments of the invention, the clock signal CLK may be provided by the host device 130, for example, the data storage device 100 may receive the clock signal CLK from the host device 130, and the transmission of the clock signal may be unidirectional. In a write operation, the data storage device 100 may receive the clock signal CLK from the host device 130 and receive data that the host device 130 intends to write or store in the memory device 120 according to the clock signal CLK. In a read operation, the data storage device 100 may receive the clock signal CLK from the host device 130 and output the data read from the memory device 120 according to the clock signal CLK.

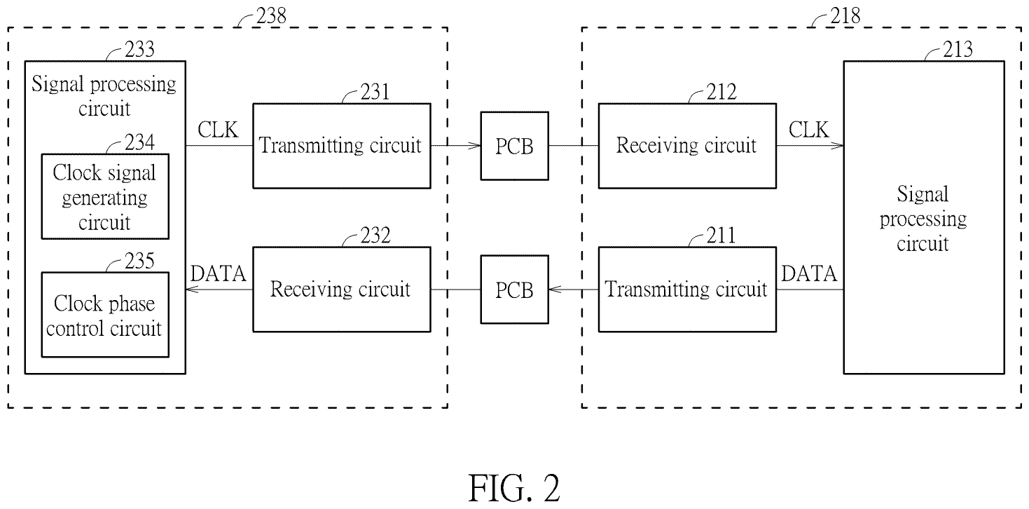

FIG. 2 shows an exemplary circuit diagram of a portion of circuits in the host interface and a portion of circuits in the device interface, for illustrating the signal transmission path between the data storage device (e.g., the data storage device 100) and the host device (e.g., the host device 130), according to an embodiment of the invention.

The host interface 218 may at least comprise a transmitting circuit 211 on the signal transmission path (e.g., the TX_Path 128 shown in FIG. 1), a receiving circuit 212 on the signal reception path (e.g., the RX_Path 126 shown in FIG. 1) and a signal processing circuit 213. The device interface 238 may at least comprise a transmitting circuit 231 on a signal transmission path, a receiving circuit 232 on a signal reception path and a signal processing circuit 233. The transmitting circuit 211, the receiving circuit 212 and the signal processing circuit 213 are respectively configured to perform necessary signal processing of the host interface 218, and the transmitting circuit 231, the receiving circuit 232 and the signal processing circuit 233 are respectively configured to perform necessary signal processing of the device interface 238.

As described above, the clock signal CLK required by the data storage device may be provided by the host device. The host device may provide clock signal CLK through the transmitting circuit 231 thereof to the data storage device. The clock signal CLK provided by the host device may travel from an output pad in the transmitting circuit 231 through the Printed Circuit Board (PCB) to an input pad in the receiving circuit 212. In some implementations, the clock signal CLK may be further provided to the signal processing circuit 213 to assist operations of the signal processing circuit 213.

The data storage device may output data DATA read from the memory device (e.g., the memory device 120) through the transmitting circuit 211 thereof to the host device. The receiving circuit 232 of the host device may receive the data DATA read from the memory device through PCB and provide the data DATA to the signal processing circuit 233. The signal processing circuit 233 may further process the data DATA.

According to an embodiment of the invention, the signal processing circuit 233 may comprise at least a clock signal generating circuit 234. The clock signal generating circuit 234 may comprise a delay locked loop (DLL) circuit and may generate a predetermined reference clock signal CLK′ based on the clock signal CLK (which is a fundamental clock signal) provided to the data storage device with a phase (i.e., a sampling phase) currently set to latch or sample (hereinafter using the term ‘sample’ (as well as ‘sampling’ or ‘sampled’) for brevity) the data DATA.

In an initialization procedure, the host device may estimate the sampling phase utilized to sample the data DATA received from the data storage device and apply the sampling phase to generate the predetermined reference clock signal CLK′, which is a clock signal reproduced or regenerated by the host device based on the clock signal CLK and the sampling phase. In the read operation, the host device may sample the data DATA received from the data storage device according to the predetermined reference clock signal CLK′ reproduced by itself. The predetermined reference clock signal CLK′ reproduced by the host device may be a replica of the clock signal CLK provided by the host device and utilized by the data storage device for outputting the data DATA. For example, the clock signal CLK and the predetermined reference clock signal CLK′ have the same frequency.

However, the phase delay of the clock signal CLK utilized by the data storage device for outputting the data DATA may be affected by many factors. Among them, one key factor may be the temperature. For example, when the temperature increases, the phase delay of the clock signal CLK increases as well. As the phase delay of the clock signal CLK increases, the sampling phase previously estimated and utilized for reproducing the clock signal (i.e., utilized for generating the predetermined reference clock signal CLK′) may become unaligned with the phase of the clock signal CLK utilized to output the data DATA read from the memory device, thereby decreasing the margin to correctly sample data and increasing the error rate of sampling data at the host device. For example, when the phase different between the clock signal CLK and the predetermined reference clock signal CLK′ exceeds the margin to correctly sample data, an erroneous sampling result may be obtained.

The data error rate may be further increased when the data rate (data transmission rate) between the data storage device and the host device increases, due to the reason that the margin to correctly sample data decreases. To avoid obtaining erroneous sampling result at the host device due to unexpected change in phase delay, a novel clock phase control method and the associated circuit structure implementing the clock phase control method are proposed to control of the clock phase utilized for sampling data read from the data storage device.

According to an embodiment of the invention, the clock signal generating circuit 234 may generate a plurality of reference clock signals based on the clock signal CLK (fundamental clock signal) with different candidate phases. The candidate phases may comprise the sampling phase of the fundamental clock signal currently set to sample the data, and thus, the plurality of reference clock signals may comprise the aforementioned predetermined reference clock signal CLK′ which is actually utilized to sample the data DATA.

According to an embodiment of the invention, the signal processing circuit 233 may further comprise a clock phase control circuit 235. The clock phase control circuit 235 may repeatedly or consecutively determine an optimal phase according to a plurality of sampling results obtained based on the reference clock signals and provide information regarding the optimal phase to the clock signal generating circuit 234, to control the clock phase which is actually utilized to sample the data by dynamically adjusting the sampling phase of the fundamental clock signal.

According to an embodiment of the invention, the data read from the memory device may comprise data in one or more data blocks which are sequentially received in response to a read command.

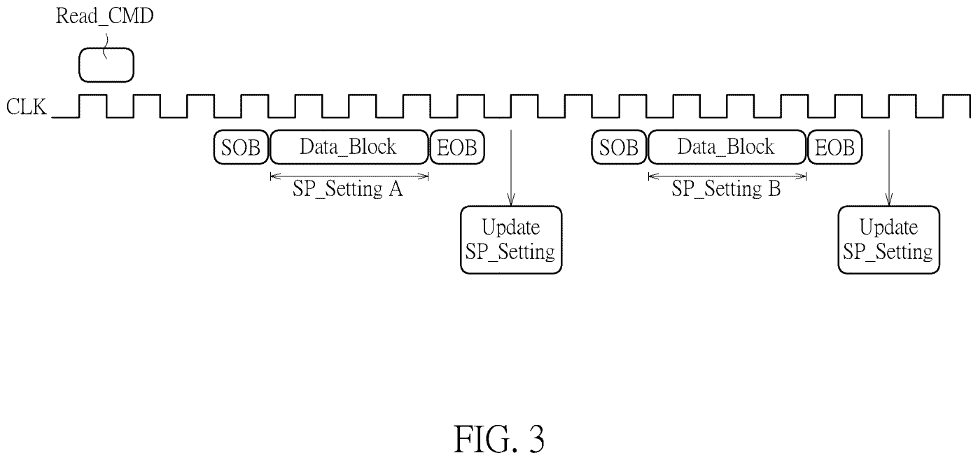

FIG. 3 shows an exemplary timing diagram of data transmission in response to a read command issued by the host device according to an embodiment of the invention. In response to a read command (labeled as ‘Read_CMD’) issued by the host device, the data storage device may output the data DATA read from the memory device in one or more data blocks (labeled as ‘Data_Block’). One indicator SOB may be utilized to indicate a start of a data block transmission, and another indicator EOB may be utilized to indicate an end of the data block transmission. Transmission of the data block Data_Block may follow the indicator SOB, and may be followed by the indicator EOB.

According to an embodiment of the invention, the clock phase control circuit 235 may consecutively provide information regarding the optimal phase to the clock signal generating circuit 234 to adjust the sampling phase of the fundamental clock signal in response to an end of each data block (for example, at the end of each data block or after the end of each data block), such as the operations of ‘UpdateSP_Setting’ shown in FIG. 3. As shown in FIG. 3, a first sampling phase setting SP_Setting_A is applied to sample data in a first data block which is received in response to the read command Read_CMD. After the operation of ‘Update SP_Setting’, the sampling phase setting may be adjusted and changed to a second sampling phase setting SP_Setting_B. Then, the second sampling phase setting SP_Setting_B is applied to sample data in a second data block which is successively received in response to the same read command Read_CMD. In the embodiments of the invention, the first sampling phase setting (e.g., the sampling phase setting SP_Setting_A) and the second sampling phase setting (e.g., the sampling phase setting SP_Setting_B) may be the same or different.

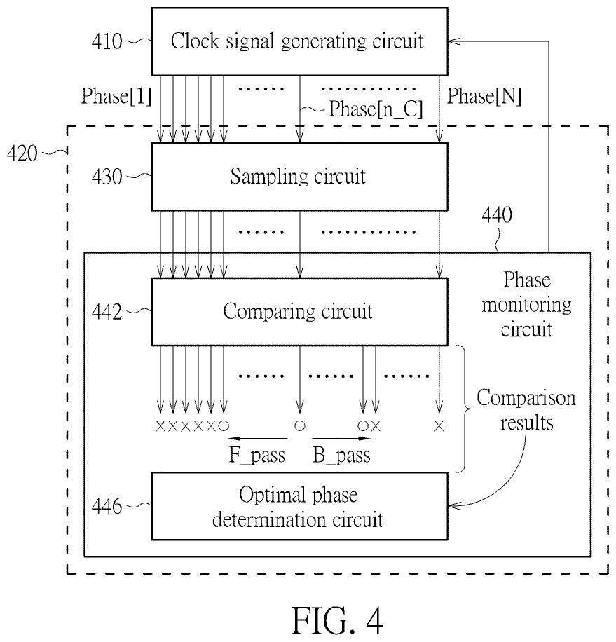

FIG. 4 is a schematic diagram of the proposed clock phase control implemented by the clock signal generating circuit and the clock phase control circuit according to an embodiment of the invention. The clock signal generating circuit 410 may generate the reference clock signals with different candidate phases based on the clock signal CLK (fundamental clock signal). According to an embodiment of the invention, there may be N candidate phases, such as the candidate phases Phase[1]-Phase[N] shown in FIG. 4, where the values 1-N represent the phase indexes and N is a positive integer greater than 1.

The candidate phases may comprise a sampling phase, such as the phase Phase[n_C], of the fundamental clock signal currently set to sample the data. According to an embodiment of the invention, the sampling phase of the fundamental clock signal currently set to sample the data may be a center of a margin (e.g., a center phase of a time margin or a phase margin) to correctly sample data determined in the initialization procedure.

According to an embodiment of the invention, the clock phase control circuit 420 may comprise a sampling circuit 430 and a phase monitoring circuit 440. The sampling circuit 430 may receive the reference clock signals and, in response to the read command (such as the read command Read_CMD shown in FIG. 3), sample the data DATA according to the reference clock signals to obtain the sampling results.

According to an embodiment of the invention, the data DATA read from the memory device may comprise data in one or more data blocks which are sequentially transmitted in response to the read command, such as the data blocks ‘Data Block’ shown in FIG. 3, and sequentially received by the host device. Take a predetermined data block of the one or more data blocks as an example, according to an embodiment of the invention, the sampling results may comprise a plurality of predetermined sampling results obtained based on the data in the predetermined data block, and the sampling circuit 430 may consecutively sample the data in the predetermined data block at a plurality of edges of the reference clock signals (which are generated based on the clock signal CLK) to obtain the predetermined sampling results. According to an embodiment of the invention, the plurality of edges of the reference clock signals may comprise a plurality of consecutive or successive edges, such as the edges consecutively or successively arrive.

According to an embodiment of the invention, the plurality of edges may comprise at least one or both of a plurality of rising edges and a plurality of falling edges of the reference clock signals. According to another embodiment of the invention, the plurality of edges may comprise at least one or both of a plurality of consecutive or successive rising edges and a plurality of consecutive or successive falling edges of the reference clock signals. When the data is sampled at both of the rising edges and the falling edges of the predetermined reference clock signal or the reference clock signals, the double data rate (DDR) type data transmission is implemented.

The phase monitoring circuit 440 may receive the sampling results and determine the optimal phase according to the sampling results. According to an embodiment of the invention, the phase monitoring circuit 440 may comprise a comparing circuit 442 and an optimal phase determination circuit 446.

The comparing circuit 442 may receive the predetermined sampling results and compare the predetermined sampling results corresponding to the candidate phases with the predetermined sampling result (e.g., the first predetermined sampling result) corresponding to the sampling phase (e.g., the phase Phase[n_C] shown in FIG. 4) to generate a plurality of comparison results.

The optimal phase determination circuit 446 may receive the comparison results and determine the optimal phase according to the comparison results. According to an embodiment of the invention, in response to an end of the predetermined data block (for example, at the end of the predetermined data block or after the end of the predetermined data block), the phase monitoring circuit 440 may provide information regarding the determined optimal phase to the clock signal generating circuit 410 to adjust the sampling phase (e.g., the phase Phase[n_C] shown in FIG. 4) of the fundamental clock signal.

Note that in the embodiments of the invention, to effectively control the clock phase utilized for sampling data, the sampling phase of the fundamental clock signal to sample the data read from the memory device may be dynamically adjusted according to the optimal phase determined in response to the end of each data block, such as the successive operations of ‘Update SP_Setting’ shown in FIG. 3. For example, after the end of each data block, the phase monitoring circuit 446 may determine the optimal phase according to the latest received comparison results and provide information regarding the latest determined optimal phase to the clock signal generating circuit 410 to adjust the sampling phase of the fundamental clock signal. However, it is to be noted that the frequency to adjust the sampling phase is not limited thereto. In other embodiments of the invention, the sampling phase may also be updated or adjusted in response to the end of multiple data blocks, or updated or adjusted periodically or aperiodically during the data transmission based on the latest received comparison results.

According to an embodiment of the invention, the comparison results may indicate whether the sampling result associated with a corresponding candidate phase is correct or not. For example, a first comparison result may be obtained by comparing the sampling result corresponding to the first candidate phase Phase[1] with the sampling result corresponding to the sampling phase Phase[n_C]. When the sampling result corresponding to the first candidate phase Phase[1] is different from the sampling result corresponding to the sampling phase Phase[n_C], the first comparison result associated with the sampling result corresponding to the first candidate phase Phase[1] may be set to a first value indicating that the corresponding sampling result is incorrect (represented by the cross symbol ‘X’ in FIG. 4).

For another example, a second comparison result may be obtained by comparing the sampling result corresponding to the second candidate phase Phase[n_C−1] with the sampling result corresponding to the sampling phase Phase[n_C]. When the sampling result corresponding to the second candidate phase Phase[n_C−1] is the same as the sampling result corresponding to the sampling phase Phase[n_C], the second comparison result associated with the sampling result corresponding to the second candidate phase Phase[n_C−1] may be set to a second value indicating that the corresponding sampling result is correct (represented by the circle symbol ‘O’ in FIG. 4).

According to an embodiment of the invention, the optimal phase determination circuit 446 may further determine a margin to correctly sample the data in the predetermined data block according to the comparison results, and determine the optimal phase according to the margin. A pattern of the margin may be derived according to the comparison results. As shown in FIG. 4, the range of the comparison result being set to the second value depicts the pattern of the margin to correctly sample the data.

According to an embodiment of the invention, the pattern of the margin may be defined by the indexes (such as the values 1-N) of the candidate phases at which the data is correctly sampled, and the edges of the margin may be defined by the indexes of the smallest and the greatest candidate phases at which the data is correctly sampled. In addition, as the edges of the margin are located (for example, located by the corresponding phase indexes), the distances between the edges and the sampling phase currently set to sample the data may also be obtained. For example, the distances F_pass and the B_pass in FIG. 4 respective show the distances between the edges of the margin and the sampling phase currently set to sample the data, where the letter F represents a forward direction and the letter B represents a backward direction.

According to an embodiment of the invention, the pattern of the margin may be updated based on the comparison results which are latest received, and at the end of the predetermined data block, an intersection of the margins derived based on the sampling results sampled at different clock edges (e.g., the rising edges and/or falling edges of the reference clock signals) may be obtained.

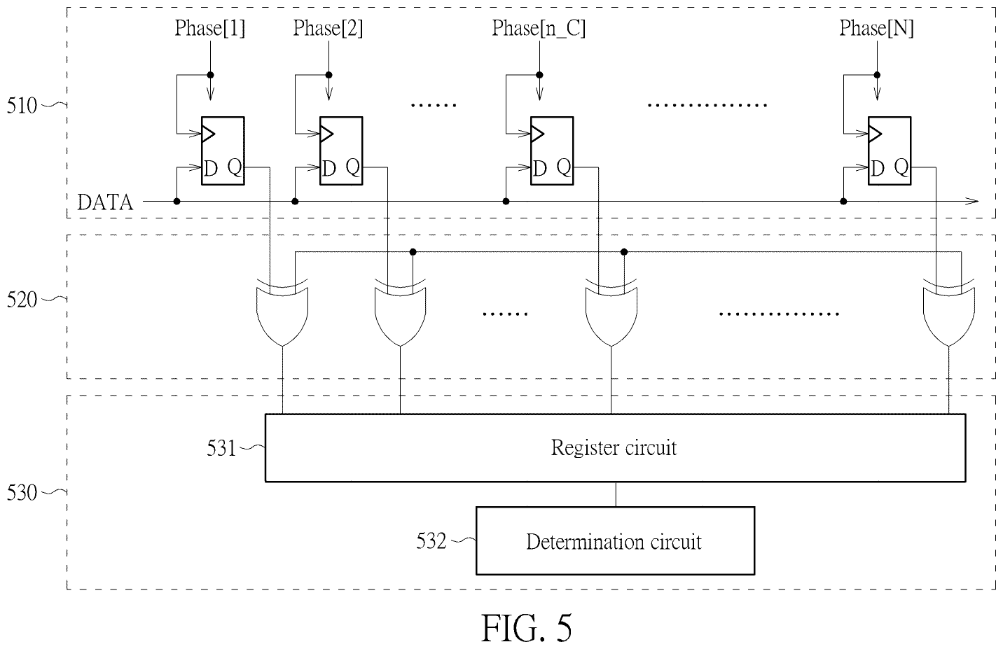

FIG. 5 shows an exemplary circuit diagram of the phase control circuit according to an embodiment of the invention. The sampling circuit 510 may comprise N flip-flops (FFs). The number of FFs may be associated with the number of candidate phases Phase[1], Phase[2], . . . . Phase[N]. Each FF receives a reference clock signal with a candidate phase, keeps sampling the data DATA at successive edges of the corresponding reference clock signal and sequentially outputs a corresponding sampling result.

The comparing circuit 520 may comprise N comparators. In an embodiment of the invention, the comparators may be implemented by the XOR gates as shown in FIG. 5. Suppose that the candidate phase Phase[n_C] is the sampling phase of the fundamental clock signal currently set to sample the data and the sampling result of the sampling phase Phase[n_C] is correct, each comparator compares the sampling result corresponding to one candidate phase with the sampling result corresponding to the sampling phase Phase[n_C] and generates a corresponding comparison result.

According to an embodiment of the invention, the optimal phase determination circuit 530 may comprise a register circuit 531 and a determination circuit 532. The register circuit 531 receives the comparison results sequentially generated based on the sampling results obtained at the successive edges of the reference clock signals and updates a pattern of the margin based on the comparison results which are latest received.

Take the predetermined data block of the one or more data blocks as an example, according to an embodiment of the invention, the register circuit 531 receives the comparison results sequentially generated based on the predetermined sampling results obtained by sampling the data in the predetermined data block at the successive edges of the reference clock signals. The pattern of the margin may be defined by the indexes (such as the numbers 1-N) of the candidate phases at which the data is correctly sampled, and register circuit 531 may keep updating the pattern of the margin based on the sampling results obtained at different clock edges (e.g., the rising edges and/or falling edges) of the reference clock signals.

For example, the register circuit 531 may keep updating the pattern of the margin by, for example but not limited to, performing an OR operation on a previously received comparison result corresponding to one candidate phase (or, registered data) and a latest received comparison result (e.g., the latest output of the XOR gate) corresponding to the same candidate phase and registering the operation result as the registered data for further use. In this manner, an intersection of the margins derived based on the comparison results associated with the sampling results sampled at different clock edges (e.g., the rising edges and/or falling edges of the reference clock signals) may be obtained.

According to an embodiment of the invention, the determination circuit 532 may locate a first edge (e.g., a left edge or an edge in the forward direction) of the margin and a second edge (e.g., a right edge or an edge in the backward direction) of the margin, and locate the optimal phase according to the first edge and the second edge. According to an embodiment of the invention, the determination circuit 532 may obtain a first phase index of the first edge, obtain a second phase index of the second edge, and obtain a phase index of the optimal phase according to the first phase index and the second phase index. According to an embodiment of the invention, the determination circuit 532 may determine an adjustment of the sampling phase of the fundamental clock signal so as to shift the sampling phase to the optimal phase according to the first phase index and the second phase index.

According to an embodiment of the invention, the determination circuit 532 may locate the edges or the phase indexes of the edges based on the pattern of the margin finally obtained by the register circuit 531 after the end of each data block.

In addition, when the data transmission in the predetermined data block is ended, (e.g., when the indicator EOB is received), the determination circuit 532 may receive information regarding the pattern of the final margin from the register circuit 531, which may be the intersection of the margins (i.e., the intersection of the comparison results corresponding to each candidate phase and successively output by the comparing circuit 520) and locate the edges of the margin or the phase indexes of the edges of the margin based on the pattern of the final margin.

According to an embodiment of the invention, the optimal phase may be a center phase in the final margin. Suppose that the value n_F is the phase index of a first edge (e.g., a left edge or an edge in the forward direction) of the final margin, the value n_B is the phase index of a second edge (e.g., a right edge or an edge in the backward direction) of the final margin, and the value n_C is the phase index of the sampling phase currently set to sample the data, the optimal phase is the center phase in the final margin and the phase index of the optimal phase may be determined by as the following equations:

$$n\_C - ( n\_F - n\_B ) / 2 , when n\_F > n\_B \qquad Eq . ( 1 )$$

$$n\_C + ( n\_B - n\_F ) / 2 , when n\_B > n\_F \qquad Eq . ( 2 )$$

In the embodiments of the invention, information regarding the optimal phase may be the phase index of the located optimal phase or the adjustment of the sampling phase of the fundamental clock signal to shift the sampling phase to the optimal phase.

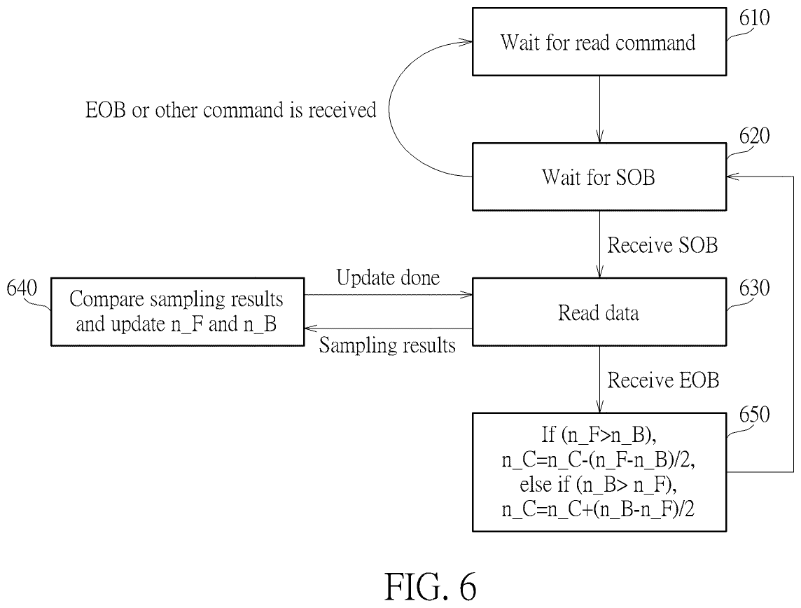

FIG. 6 shows an exemplary state machine to perform clock phase control according to an embodiment of the invention. At state 610, the device interface may wait for the read command issued by the processor of the electronic device (e.g., the processor 131 of the host device 130 as shown in FIG. 1). State 610 may be entered when the indicator EOB or other command is received. In response to the reception of the read command, state 620 is entered. At state 620, the device interface may wait for the indicator SOB. In response to the reception of the indicator SOB is received, state 630 is entered. At state 630, the device interface may read the data provided by the data storage device in response to the read command, which includes the operations of sampling the data. Before the indicator EOB is received, the device interface may jump to state 640 upon obtaining the sampling results to compare the sampling results and update the phase indexes n_F and n_B of the edges of the margin currently obtained based on the latest comparison results. The device interface may jump to state 630 to keep sampling the data when the update of phase indexes n_F and n_B of the edges is done. When the indicator EOB is received, the device interface may jump to state 650 to determine the new phase index of the sampling phase set to sample the data as equations Eq. (1) and Eq. (2) described above. In the embodiment shown in FIG. 6, the phase index n_C of the sampling phase set to sample the data is updated or adjusted to a new value based on the adjustment of the sampling phase of the fundamental clock signal to shift the sampling phase to the newly determined optimal phase, that is, [n_C=n_C−(n_F−n_B)/2] or [n_C=n_C+ (n_B−n_F)/2] as shown in FIG. 6.

In the conventional design, the host device may estimate the sampling phase utilized to sample the data received from the data storage device in the initialization procedure to obtain a sampling phase setting, and the sampling phase setting will not be changed. However, when the temperature increases, the sampling phase previously estimated may become unaligned with the phase of the clock signal CLK which is actually utilized by the data storage device to output the data read from the memory device, thereby increasing the error rate of sampling data at the host device.

Different from the conventional design, in the embodiments of the invention, the sampling phase utilized to sample the data received from the data storage device is updated or adjusted in response to the transmission of each data block, for example, updated or adjusted after every data block transmission. Or, in other embodiments of the invention, the sampling phase utilized to sample the data received from the data storage device is updated or adjusted in response to the end of multiple data blocks, or updated or adjusted periodically or aperiodically during the data transmission based on the latest received comparison results. That is, in the embodiments of the invention, the sampling phase utilized to sample the data received from the data storage device keeps being updated or adjusted during the data transmission based on the latest received comparison results. In the embodiments of the invention, in response to the same read command, the sampling phase utilized to sample the data received from the data storage device may be repeatedly adjusted or may be adjusted for several times, such as the operations of ‘Update SP_Setting’ shown in FIG. 3. Or, the host device may use different sampling phases to sample the data received from the data storage device in response to the same read command.

In other words, different from the conventional design in which the sampling phase setting is estimated in the initialization procedure and will be no longer changed unless data error occurs, in the embodiments of the invention, the host device keeps updating or adjusting the sampling phase during the data transmission based on the latest received comparison results. Especially, the sampling phase will keep being updated or adjusted based on the latest received comparison results during the data transmission in response to a single read command. In this manner, no matter how the actual optimal phase to correctly sample the data changes (for example, changed due to high temperature or other reasons), the sampling phase actually utilized to sample the data received from the data storage device can always be quickly and accurately locked to the actual optimal phase to correctly sample the data, and erroneous sampling result can be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A clock phase control circuit, comprising:
a sampling circuit, receiving a plurality of reference clock signals and, in response to a read command, sampling data read from a memory device according to the reference clock signals to obtain a plurality of sampling results, wherein the reference clock signals are generated based on a fundamental clock signal with different candidate phases; and
a phase monitoring circuit, receiving the sampling results and determining an optimal phase according to the sampling results,
wherein the data read from the memory device comprises data in one or more data blocks which are sequentially received in response to the read command, and
wherein in response to an end of each data block, a sampling phase of the fundamental clock signal to sample the data read from the memory device is adjusted according to the optimal phase.

2. The clock phase control circuit of claim 1, wherein the reference clock signals are generated by a clock signal generating circuit, and in response to the end of each data block, the phase monitoring circuit determines the optimal phase and provides information regarding the optimal phase to the clock signal generating circuit to adjust the sampling phase of the fundamental clock signal.

3. The clock phase control circuit of claim 1, wherein the sampling results comprise a plurality of predetermined sampling results obtained based on the data in a predetermined data block of the one or more data blocks, and the sampling circuit consecutively samples the data in the predetermined data block at a plurality of edges of the reference clock signals to obtain the predetermined sampling results.

4. The clock phase control circuit of claim 3, wherein the edges comprise at least one of a plurality of rising edges and a plurality of falling edges of the reference clock signals.

5. The clock phase control circuit of claim 3, wherein the candidate phases comprise the sampling phase of the fundamental clock signal currently set to sample the data, the predetermined sampling results comprise a first predetermined sampling result corresponding to the sampling phase of the fundamental clock signal, and the phase monitoring circuit comprises:
a comparing circuit, receiving the predetermined sampling results and comparing the predetermined sampling results corresponding to the candidate phases with the first predetermined sampling result corresponding to the sampling phase to generate a plurality of comparison results; and
an optimal phase determination circuit, receiving the comparison results and determining the optimal phase according to the comparison results.

6. The clock phase control circuit of claim 5, wherein the optimal phase determination circuit further determines a margin to correctly sample the data in the predetermined data block according to the comparison results, and determines the optimal phase according to the margin.

7. The clock phase control circuit of claim 6, wherein the optimal phase determination circuit comprises:
a register circuit, receiving the comparison results sequentially generated based on the predetermined sampling results obtained at the edges of the reference clock signals and updating a pattern of the margin based on the comparison results which are latest received; and
a determination circuit, locating a first edge of the margin and a second edge of the margin according to the pattern and locating the optimal phase according to the first edge and the second edge.

8. The clock phase control circuit of claim 7, wherein the optimal phase is a center phase in the margin.

9. An electronic device, coupled to a data storage device, comprising:
a receiving circuit, receiving data read from a memory device of the data storage device; and
a signal processing circuit, processing the data read from the memory device, wherein the data comprises data in one or more data blocks which are sequentially received in response to a read command, and wherein the signal processing circuit comprises:
a clock signal generating circuit, generating a plurality of reference clock signals based on a fundamental clock signal with different candidate phases, wherein the candidate phases comprise a sampling phase of the fundamental clock signal currently set to sample the data; and
a clock phase control circuit, repeatedly determining an optimal phase according to a plurality of sampling results obtained according to the reference clock signals and providing information regarding the optimal phase to the clock signal generating circuit to adjust the sampling phase of the fundamental clock signal in response to an end of each data block.

10. The electronic device of claim 9, wherein the clock signal generating circuit comprises a delay locked loop circuit.

11. The electronic device of claim 9, wherein the clock phase control circuit comprises:
a sampling circuit, receiving the reference clock signals and, in response to the read command, sampling the data according to the reference clock signals to obtain the sampling results; and
a phase monitoring circuit, receiving the sampling results and determining the optimal phase according to the sampling results.

12. The electronic device of claim 11, wherein the sampling results comprise a plurality of predetermined sampling results obtained based on the data in a predetermined data block of the one or more data blocks, and the sampling circuit consecutively samples the data in the predetermined data block at a plurality of edges of the reference clock signals to obtain the predetermined sampling results.

13. The electronic device of claim 12, wherein the edges comprise at least one of a plurality of rising edges and a plurality of falling edges of the reference clock signals.

14. The electronic device of claim 12, wherein the predetermined sampling results comprise a first predetermined sampling result corresponding to the sampling phase of the fundamental clock signal, and the phase monitoring circuit comprises:
a comparing circuit, receiving the predetermined sampling results and comparing the predetermined sampling results corresponding to the candidate phases with the first predetermined sampling result corresponding to the sampling phase to generate a plurality of comparison results; and
an optimal phase determination circuit, receiving the comparison results and determining the optimal phase according to the comparison results.

15. The electronic device of claim 14, wherein the optimal phase determination circuit further determines a margin to correctly sample the data in the predetermined data block according to the comparison results, and determines the optimal phase according to the margin.

16. The electronic device of claim 15, wherein the optimal phase determination circuit comprises:
a register circuit, receiving the comparison results sequentially generated based on the predetermined sampling results obtained at the edges of the reference clock signals and updating a pattern of the margin based on the comparison results which are latest received; and
a determination circuit, locating of a first edge of the margin and of a second edge of the margin according to the pattern and locating the optimal phase according to the first edge and the second edge.

17. The electronic device of claim 16, wherein the optimal phase is a center phase in the margin.
